(19) United States
(12) Patent Application Publication
(10) Pub. No.: US 2025/0070076 A1
(43) Pub. Date: Feb. 27, 2025

(54) SEMICONDUCTOR DEVICE

(71) Applicant: Rohm Co., Ltd., Kyoto-shi (JP)

(72) Inventor: Hiroaki MATSUBARA, Kyoto-shi (JP)

(21) Appl. No.: 18/946,363

(22) Filed: Nov. 13, 2024

Related U.S. Application Data
(63) Continuation of application No. PCT/JP2023/017144, filed on May 2, 2023.

(30) Foreign Application Priority Data
May 16, 2022 (JP) 2022-080342

(51) Int. Cl. H01L 23/00; H01L 23/495; H01L 25/065

(52) U.S. Cl. CPC H01L 24/48; H01L 24/85; H01L 23/49575; H01L 25/0655; H01L 2224/48137; H01L 2224/48245; H01L 2224/48479; H01L 2224/85051

(57) ABSTRACT

A semiconductor device includes a first wire, a first semiconductor element including an electrode electrically connected to the first wire, and a bump electrically bonded to the electrode. The first wire includes a first bonding portion located at one end and a second bonding portion located at another end. The bump includes a disc portion in contact with the electrode, and a pillar portion protruding from the disc portion in a first direction. The second bonding portion is electrically bonded to the pillar portion. A dimension of the pillar portion in the first direction increases as approaching the first bonding portion.

### TECHNICAL FIELD

The present disclosure relates to a semiconductor device.

### BACKGROUND ART

The semiconductor device disclosed in JP-A-2016-207714 includes a control element (controller) and a drive element (gate driver). The semiconductor device drives a switching element such as an IGBT. Thus, the semiconductor device is used in an inverter circuit, for example.

In the semiconductor device, the source voltage supplied to the drive element is equal to or higher than the voltage applied to the switching element. Accordingly, the source voltage supplied to the control element is different from the source voltage supplied to the drive element. As a result, there is a difference between the voltage applied to the control element and its conductive path and the voltage applied to the drive element and its conductive path.

Therefore, in the semiconductor device, an insulating element is interposed in the electric signal transmission path between the control element and the drive element so as to insulate the control element and its conductive path from the drive element and its conductive path. This prevents electric breakdown of the control element and the drive element.

The semiconductor device further includes a plurality of wires formed by wire bonding. Some of the wires are electrically bonded to the control element and the insulating element. Furthermore, some of the wires are electrically bonded to the insulating element and the drive element. Thus, a wedge bonding portion of one of the wires is electrically bonded to at least one semiconductor element among the control element, the drive element, and the insulating element. When the wedge bonding portion is electrically bonded to the semiconductor element, the wire may make contact with an edge of the semiconductor element. In this case, there is risk of a short circuit between the semiconductor element and the wire.

### BRIEF DESCRIPTION OF THE DRAWINGS

FIG. 1 is a plan view showing a semiconductor device according to a first embodiment of the present disclosure.

FIG. 2 is a plan view corresponding to FIG. 1, in which a sealing resin is shown by its outline only.

FIG. 3 is a front view showing the semiconductor device in FIG. 1.

FIG. 4 is a left-side view showing the semiconductor device in FIG. 1.

FIG. 5 is a right-side view showing the semiconductor device in FIG. 1.

FIG. 6 is a cross-sectional view taken along line VI-VI in FIG. 2.

FIG. 7 is a cross-sectional view taken along line VII-VII in FIG. 2.

FIG. 8 is a partially enlarged view of FIG. 2.

FIG. 9 is a partially enlarged view of FIG. 6, showing a first semiconductor element, a second semiconductor element, and an area near these semiconductor elements.

FIG. 10 is a partially enlarged view of FIG. 6, showing the second semiconductor element, a third semiconductor element, and an area near these semiconductor elements.

FIG. 11 is a partially enlarged view of FIG. 8.

FIG. 12 is a partially enlarged view of FIG. 9.

FIG. 13 is a partially enlarged view of FIG. 10.

FIG. 14 is a partially enlarged cross-sectional view illustrating a method for forming a bump in the semiconductor device in FIG. 1.

FIG. 15 is a partially enlarged cross-sectional view illustrating the method for forming a bump in the semiconductor device in FIG. 1.

FIG. 16 is a partially enlarged cross-sectional view illustrating the method for forming a bump in the semiconductor device in FIG. 1.

FIG. 17 is a partially enlarged cross-sectional view showing a variation of the semiconductor device in FIG. 1.

FIG. 18 is a plan view showing a semiconductor device according to a second embodiment of the present disclosure, in which a sealing resin is shown by its outline only.

FIG. 19 is a cross-sectional view taken along line XIX-XIX in FIG. 18.

FIG. 20 is a partially enlarged plan view showing a semiconductor device according to a third embodiment of the present disclosure, from which illustration of a sealing resin is omitted.

FIG. 21 is a cross-sectional view showing the semiconductor device in FIG. 20, showing a first semiconductor element, a second semiconductor element, and an area near these semiconductor elements.

FIG. 22 is a cross-sectional view showing the semiconductor device in FIG. 20, showing the second semiconductor element, a third semiconductor element, and an area near these semiconductor elements.

### DETAILED DESCRIPTION OF EMBODIMENTS

Embodiments of the present disclosure will be described with reference to the accompanying drawings.

### First Embodiment

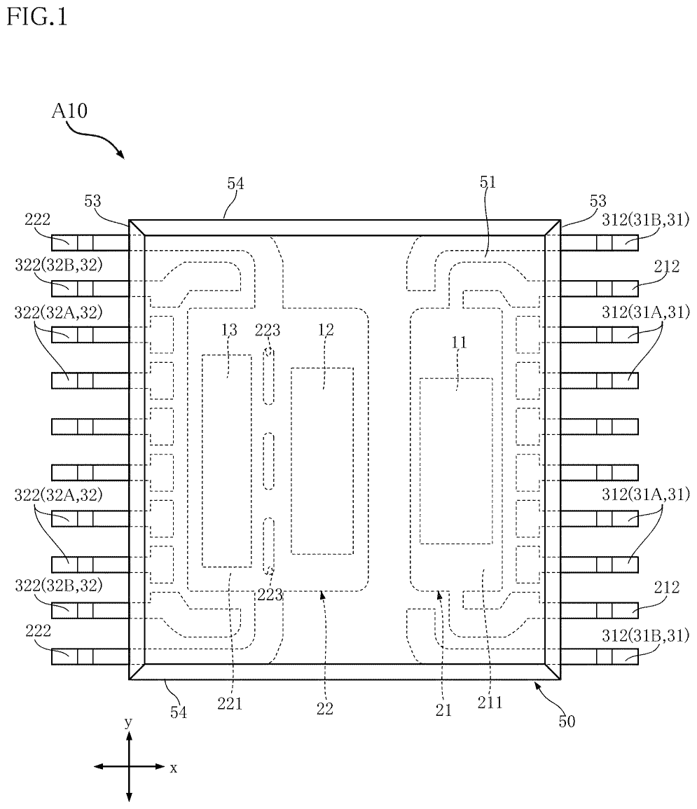

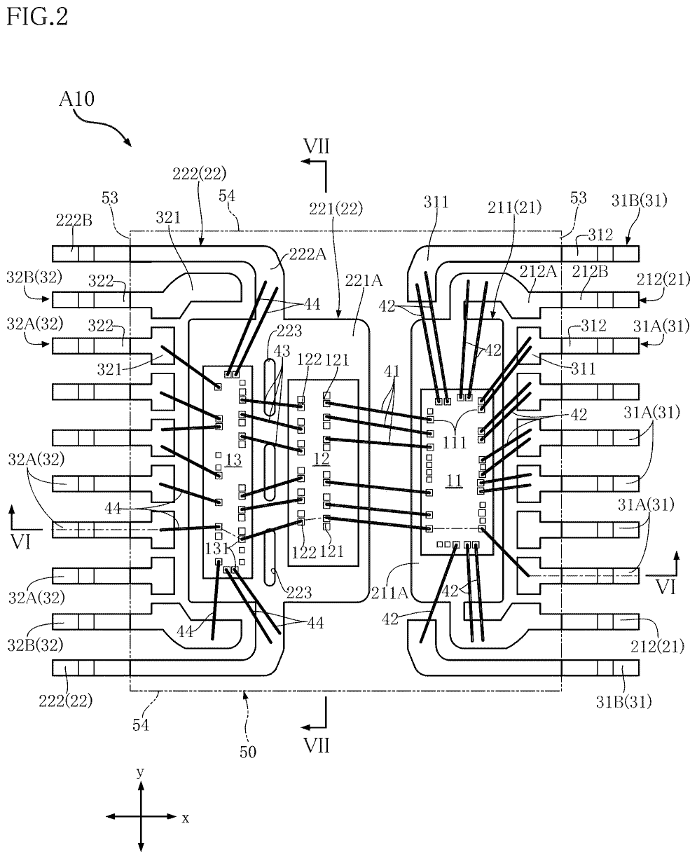

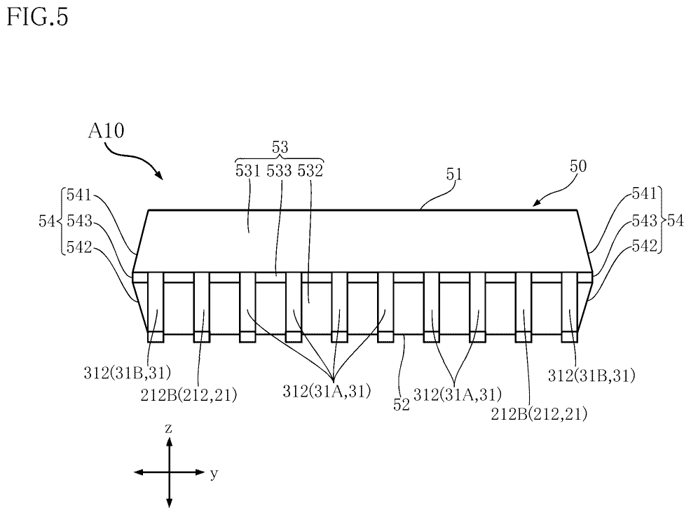

The following describes a semiconductor device A10 according to a first embodiment of the present disclosure, with reference to FIGS. 1 to 13. The semiconductor device A10 includes a first semiconductor element 11, a second semiconductor element 12, a third semiconductor element 13, a first die pad 21, a second die pad 22, a plurality of second terminals 32, a plurality of first wires 41, a plurality of second wires 42, a plurality of bumps 60, and a sealing resin 50. The semiconductor device A10 further includes a plurality of first terminals 31, a plurality of third wires 43, and a plurality of fourth wires 44. The semiconductor device A10 is surface-mounted on the wiring board of an inverter for an electric vehicle or a hybrid vehicle, for example. The semiconductor device A10 is in a small outline package (SOP). Note that the package type of the semiconductor device A10 is not limited to an SOP. In FIG. 2, the sealing resin 50 is shown by its outline only for convenience of understanding. In FIG. 2, the outline of the sealing resin 50 is indicated with an imaginary line (two-dot chain line).

In the description of the semiconductor device A10, an example of the direction that is normal to a first mounting surface 211A of a first pad portion 211 of the first die pad 21, which is described below, is referred to as a “first direction z” for convenience. An example of a direction perpendicular to the first direction z is referred to as a “second direction x”. An example of the direction perpendicular the first direction z and the second direction x is referred to as a “third direction y”.

The first element 11, semiconductor the second semiconductor element 12, and the third semiconductor element 13 form the functional core of the semiconductor device A10. In the semiconductor device A10, each of the first semiconductor element 11, the second semiconductor element 12, and the third semiconductor element 13 is an individual element. The third semiconductor element 13 is located opposite from the first semiconductor element 11 with respect to the second semiconductor element 12 in the second direction x. As viewed in the first direction z, each of the first semiconductor element 11, the second semiconductor element 12, and the third semiconductor element 13 has a rectangular shape elongated in the third direction y.

The first semiconductor element 11 drives a switching element located outside the semiconductor device A10. The switching element is, for example, an IGBT (Insulated Gate Bipolar Transistor) or a MOSFET (Metal-Oxide-Semiconductor Field-Effect Transistor). The first semiconductor element 11 includes a reception circuit for receiving a PWM control signal, a circuit for driving the switching element based on the PWM control signal, and a transmission circuit for transmitting an electric signal to the third semiconductor element 13. The electric signal may be an output signal from a temperature sensor located near a motor.

The second semiconductor element 12 transmits an electric signal such as a PWM (Pulse Width Modulation) control signal in an insulated state. The second semiconductor element 12 is of an inductive type. One example of the inductive second semiconductor element 12 is an insulating transformer. The insulating transformer transmits an electric signal in an insulated state by inductively coupling two inductors (coils). The two inductors include a transmitting-side inductor and a receiving-side inductor. Each of the two inductors is stacked in the first direction z. A dielectric layer made of, for example, silicon dioxide (SiO₂) is located between the transmitting-side inductor and the receiving-side inductor. The dielectric layer provides electrical insulation between the transmitting-side inductor and the receiving-side inductor. Alternatively, the second semiconductor element 12 may be of a capacitive type. One example of the capacitive second semiconductor element 12 is a capacitor.

The third semiconductor element 13 controls the first semiconductor element 11. The third semiconductor element 13 includes a circuit for converting an electric signal inputted from another semiconductor device into a PWM control signal, a transmission circuit for transmitting the PWM control signal to the first semiconductor element 11, and a receiving circuit for receiving an electric signal from the first semiconductor element 11.

The voltage applied to the first semiconductor element 11 is different from the voltage applied to the third semiconductor element 13. Thus, there is a potential difference between the first semiconductor element 11 and the third semiconductor element 13. In the semiconductor device A10, the voltage applied to the first semiconductor element 11 is higher than the voltage applied to the third semiconductor element 13. Furthermore, in the semiconductor device A10, the voltage supplied to the first source semiconductor element 11 is higher than the source voltage supplied to the third semiconductor element 13.

Thus, in the semiconductor device A10, a first circuit that includes the first semiconductor element 11 and a second circuit that includes the third semiconductor element 13 are insulated from each other by the second semiconductor element 12. The second semiconductor element 12 is electrically connected to the first circuit and the second circuit. The first circuit includes the first die pad 21, the first terminals 31, the first wires 41, and the second wires 42, in addition to the first semiconductor element 11. The second circuit includes the second die pad 22, the third wires 43, and the fourth wires 44, addition to the third semiconductor element 13. The first circuit and the second circuit have different potentials. In the semiconductor device A10, the potential of the first circuit is higher than the potential of the second circuit. In this state, the second semiconductor element 12 relays a mutual signal between the first circuit and the second circuit. For example, in an inverter for an electric vehicle or a hybrid vehicle, the voltage applied to the ground (GND) of the first semiconductor element 11 may transiently become 600 V or higher while the voltage applied to the ground of the third semiconductor element 13 is about 0 V.

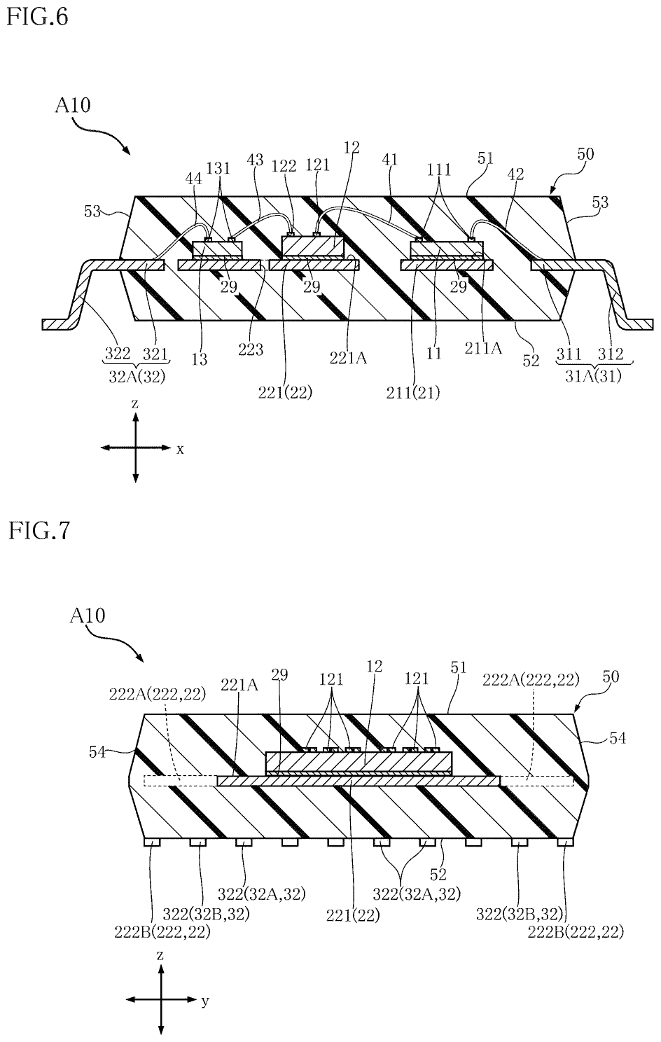

As shown in FIGS. 2 and 6, the first semiconductor element 11 has a plurality of electrodes 111. The electrodes 111 are provided on the upper surface (the surface facing in the same direction as a first mounting surface 211A of a first die pad portion 211 of the first die pad 21, which is described below) of the first semiconductor element 11. The composition of the electrodes 111 includes, for example, aluminum (Al). The electrodes 111 are electrically connected to the circuit in the first semiconductor element 11.

As shown in FIGS. 2 and 6, the second semiconductor element 12 is located between the first semiconductor element 11 and the third semiconductor element 13 in the second direction x. Thus, the third semiconductor element 13 is located opposite from the first semiconductor element 11 with respect to the second semiconductor element 12 in the second direction x. The upper surface (the surface facing in the same direction as a second mounting surface 221A of a second pad portion 221 of the second die pad 22, which is described below) of the second semiconductor element 12 is provided with a plurality of first electrodes 121 and a plurality of second electrodes 122. Each of the first electrodes 121 and the second electrodes 122 is electrically connected to one of the transmitting-side inductor and the receiving-side inductor. The first electrodes 121 are arranged in the third direction y, and are located closer to the first semiconductor element 11 than the third semiconductor element 13 in the second direction x. The second electrodes 122 are arranged in the third direction y, and are located opposite from the first semiconductor element 11 with respect to the first electrodes 121 in the second direction x. The composition of the first electrodes 121 and the second electrodes 122 includes aluminum, for example.

As shown in FIGS. 2 and 6, the third semiconductor element 13 has a plurality of electrodes 131. The electrodes 131 are provided on the upper surface (the surface facing in the same direction as a second mounting surface 221A, which is described below) of the third semiconductor element 13. The composition of the electrodes 131 includes aluminum, for example. The electrodes 131 are electrically connected to the circuit in the third semiconductor element 13.

The first die pad 21, the second die pad 22, the second terminals 32, and the first terminals 31 form a conductive path connecting the first semiconductor element 11, the second semiconductor element 12, and the third semiconductor element 13 to the wiring board on which the semiconductor device A10 is mounted. The second die pad 22, the first die pad 21, the second terminals 32, and the first terminals 31 are formed from the same lead frame. The composition of the lead frame includes copper (Cu).

As shown in FIGS. 1 and 2, the first die pad 21 and the second die pad 22 are spaced apart from each other in the second direction x. In the semiconductor device A10, the first semiconductor element 11 is mounted on the first die pad 21, and the second semiconductor element 12 and the third semiconductor element 13 are mounted on the second die pad 22. The voltage applied to the first die pad 21 is different from the voltage applied to the second die pad 22. In the semiconductor device A10, the voltage applied to the first die pad 21 is higher than the voltage applied to the second die pad 22.

As shown in FIG. 2, the first die pad 21 has a first pad portion 211 and two first suspending lead portions 212. The first semiconductor element 11 is mounted on the first pad portion 211. As shown in FIG. 6, the first pad portion 211 has a first mounting surface 211A facing in the first direction z. The first semiconductor element 11 is bonded to the first mounting surface 211A via a bonding layer 29. The bonding layer 29 is made of a paste containing metal particles. The composition of the metal particles is silver (Ag), for example. Thus, the bonding layer 29 is a conductor. Alternatively, the bonding layer 29 may be solder. The first pad portion 211 is covered with the sealing resin 50. The first pad portion 211 has a thickness of 150 μm to 200 μm, for example. The area of the first pad portion 211 is smaller than the area of a second pad portion 221 of the second die pad 22. As viewed in the second direction x, the first pad portion 211 overlaps with the second pad portion 221.

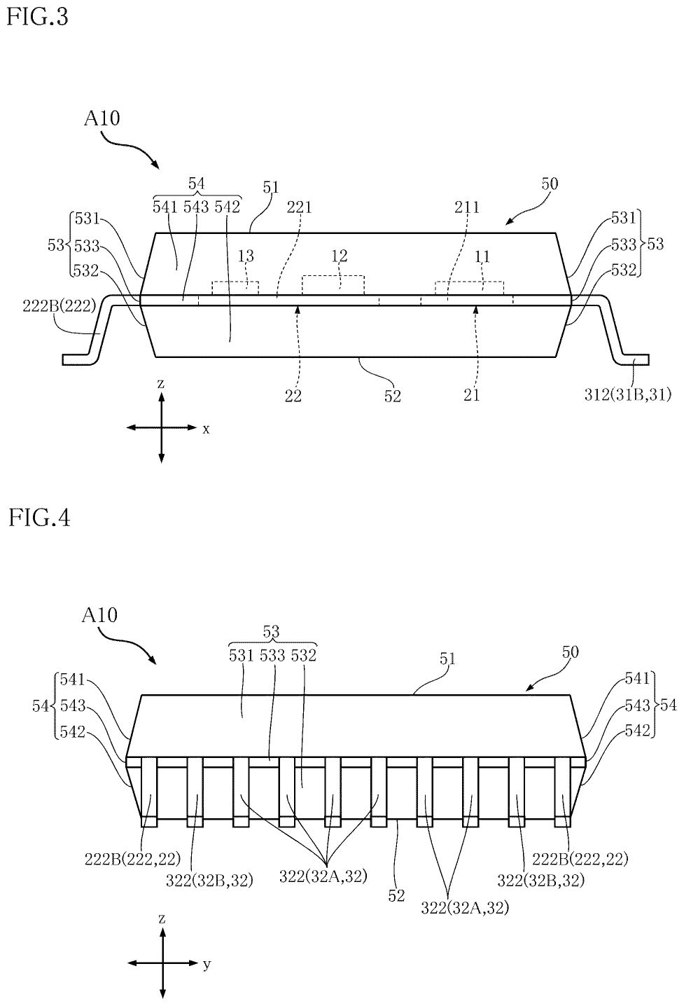

As shown in FIG. 2, the two first suspending lead portions 212 extend outward from the respective sides of the first pad portion 211 in the third direction y. Each of the two first suspending lead portions 212 has a covered portion 212A and an exposed portion 212B. The covered portion 212A is connected to the first pad portion 211 and covered with the sealing resin 50. The covered portion 212A includes a section extending in the second direction x. The exposed portion 212B is connected to the covered portion 212A and exposed from the sealing resin 50. As viewed in the first direction z, the exposed portion 212B extends in the second direction x. As shown in FIG. 3, the exposed portion 212B is bent into a gull-wing shape as viewed in the third direction y. The surface of the exposed portion 212B may be plated with tin, for example.

As shown in FIG. 2, the second die pad 22 has a second pad portion 221 and two second suspending lead portions 222. The second semiconductor element 12 and the third semiconductor element 13 are mounted on the second pad portion 221. As shown in FIGS. 6 and 7, the second pad portion 221 has a second mounting surface 221A facing in the first direction z. Each of the second semiconductor element 12 and the third semiconductor element 13 is bonded to the second mounting surface 221A via a bonding layer 29. The second pad portion 221 is covered with the sealing resin 50. The second pad portion 221 has a thickness of 150 μm to 200 μm, for example.

As shown in FIGS. 2 and 6, the second pad portion 221 is formed with a plurality of through-holes 223. Each of the through-holes 223 penetrates through the second pad portion 221 in the first direction z, and extends in the third direction y. At least one of the through-holes 223 is located between the second semiconductor element 12 and the third semiconductor element 13 in the second direction x. The through-holes 223 are arranged in the third direction y.

As shown in FIG. 2, the two second suspending lead portions 222 are connected to the respective sides of the second pad portion 221 in the third direction y. Each of the two second suspending lead portions 222 has a covered portion 222A and an exposed portion 222B. The covered portion 222A is connected to the second pad portion 221 and covered with the sealing resin 50. The covered portion 222A includes a section extending in the second direction x. The exposed portion 222B is connected to the covered portion 222A and exposed from the sealing resin 50. As viewed in the first direction z, the exposed portion 222B extends in the second direction x. As shown in FIG. 3, the exposed portion 222B is bent into a gull-wing shape as viewed in the third direction The surface of the exposed portion 222B may be plated with tin (Sn), for example.

As shown in FIGS. 1 and 2, the first terminals 31 are located opposite from the second die pad 22 with respect to the first die pad 21 in the second direction x. The first terminals 31 are arranged in the third direction y. At least one of the first terminals 31 is electrically connected to the first semiconductor element 11 via one of the second wires 42. The plurality of first terminals 31 include a plurality of first inner terminals 31A and two first outer terminals 31B. The two first suspending lead portions 212 of the first die pad 21 flank the first inner terminals 31A in the third direction y. The two first outer terminals 31B flank the first inner terminals 31A and the two first suspending lead portions 212 in the third direction y.

As shown in FIGS. 2 and 6, each of the first terminals 31 includes a covered portion 311 and an exposed portion 312. The covered portion 311 is covered with the sealing resin 50. The covered portion 311 of each of the two first outer terminals 31B is larger in dimension than the covered portion 311 of each of the first inner terminals 31A in the second direction x.

As shown in FIGS. 2 and 6, the exposed portion 312 is connected to the covered portion 311 and exposed from the sealing resin 50. As viewed in the first direction z, the exposed portion 312 extends in the second direction x. As shown in FIG. 3, the exposed portion 312 is bent into a gull-wing shape as viewed in the third direction y. The exposed portion 312 has the same shape as the exposed portion 212B of each of the two first suspending lead portions 212 of the first die pad 21. The surface of the exposed portion 312 may be plated with tin, for example.

As shown in FIGS. 1 and 2, the second terminals 32 are located opposite from the first die pad 21 with respect to the second die pad 22 in the second direction x. The second terminals 32 are arranged in the third direction y. At least one of the second terminals 32 is electrically connected to the third semiconductor element 13 via one of the fourth wires 44. The second terminals 32 are located between the two second suspending lead portions 222 of the second die pad 22 in the third direction y. The second terminals 32 include a plurality of second inner terminals 32A and two second outer terminals 32B. The two second outer terminals 32B flank the second inner terminals 32A in the third direction y.

As shown in FIGS. 2 and 6, each of the second terminals 32 includes a covered portion 321 and an exposed portion 322. The covered portion 321 is covered with the sealing resin 50. The covered portion 321 of each of the two second outer terminals 32B is larger in dimension than the covered portion 321 of each of the second inner terminals 32A in the second direction x.

As shown in FIGS. 2 and 6, the exposed portion 322 is connected to the covered portion 321 and exposed from the sealing resin 50. As viewed in the first direction z, the exposed portion 322 extends in the second direction x. The exposed portion 322 is bent into a gull-wing shape as viewed in the third direction y. The exposed portion 322 has the same shape as the exposed portion 222B of each of the two second suspending lead portions 222 of the second die pad 22. The surface of the exposed portion 322 may be plated with tin, for example.

The first wires 41, the second wires 42, the third wires 43, and the fourth wires 44, together with the first die pad 21, the second die pad 22, the first terminals 31, and the second terminals 32, form the conductive paths of the first semiconductor element 11, the second semiconductor element 12, and the third semiconductor element 13.

As shown in FIGS. 2 and 6, the first wires 41 are electrically connected to the first electrodes 121 of the second semiconductor element 12 and the electrodes 111 of the first semiconductor element 11. As a result, the second semiconductor element 12 is electrically connected to the first semiconductor element 11. As viewed in the first direction z, the first wires 41 extend in the second direction x. The first wires 41 are arranged in the third direction y. The first wires 41 extend across the space between the second pad portion 221 of the second die pad 22 and the first pad portion 211 of the first die pad 21. The composition of the first wires 41 includes gold (Au).

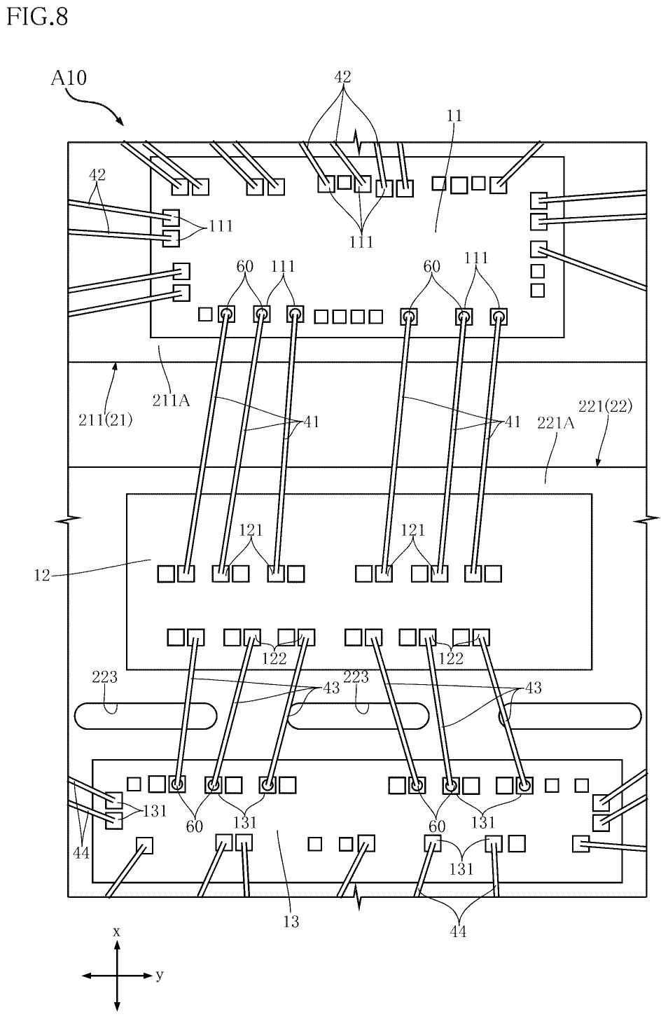

As shown in FIGS. 8 to 10, the bumps 60 are electrically bonded to some of the electrodes 111 of the first semiconductor element 11 and some of the electrodes 131 of the third semiconductor element 13, respectively. The composition of the bumps 60 is the same as the composition of the first wires 41. Thus, the composition of the bumps 60 includes gold.

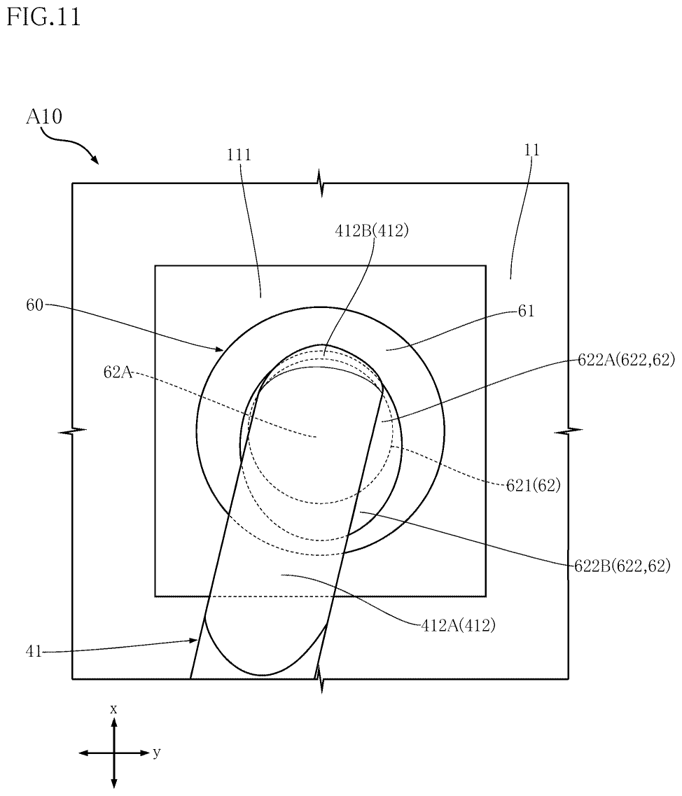

As shown in FIGS. 11 to 13, each of the bumps 60 has a disc portion 61 and a pillar portion 62. The disc portion 61 is in contact with one of the electrodes 111 of the first semiconductor element 11 and the electrodes 131 of the third semiconductor element 13. The pillar portion 62 protrudes from the disc portion 61 in the first direction z. A maximum dimension H2 of the pillar portion 62 in the first direction z is at least twice a maximum dimension H1 of the disc portion 61 in the first direction z.

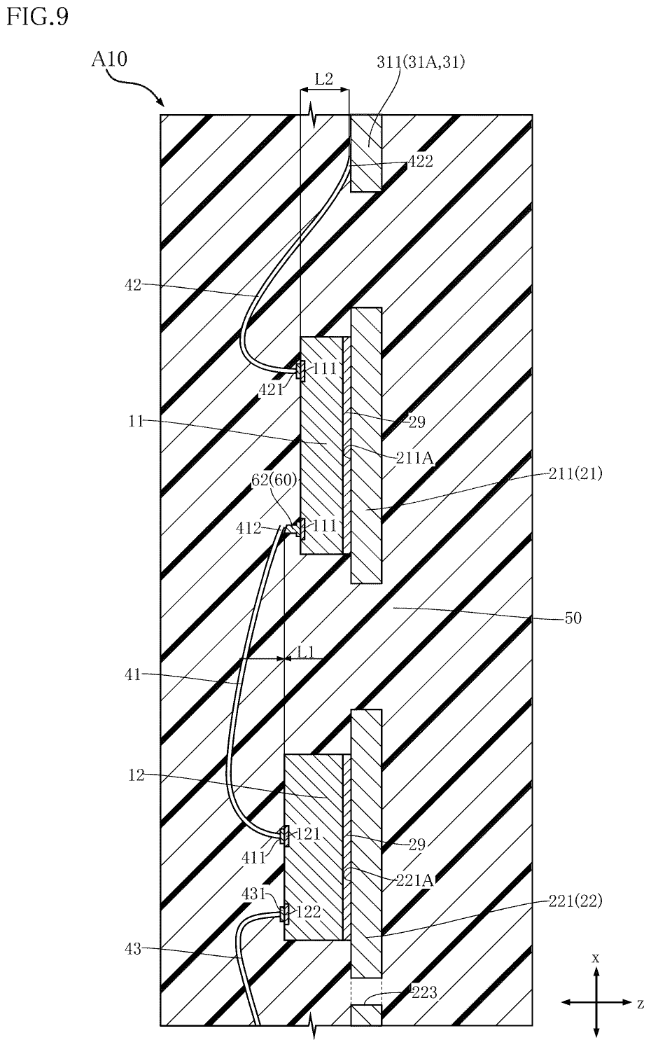

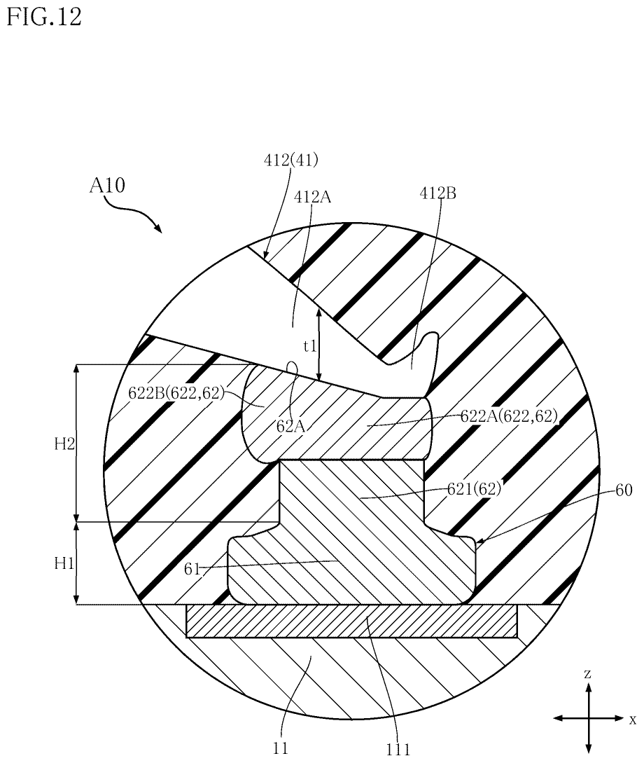

As shown in FIGS. 8 and 9, each of the first wires 41 has a first bonding portion 411 and a second bonding portion 412. The first bonding portion 411 is located at one end of the first wire 41. The first bonding portion 411 is formed by so-called ball bonding. The first bonding portion 411 is electrically bonded to one of the first electrodes 121 of the second semiconductor element 12. The second bonding portion 412 is located at the other end of the first wire 41. The second bonding portion 412 is formed by so-called wedge bonding (or stitch bonding). As shown in FIG. 12, the second bonding portion 412 is electrically bonded to the pillar portion 62 of one of the bumps 60 that are each electrically bonded to one of the electrodes 111 of the first semiconductor element 11. The dimension of the pillar portion 62 in the first direction z increases toward the first bonding portion 411.

As shown in FIG. 12, the pillar portion 62 of each bump 60 electrically bonded to one of the electrodes 111 of the first semiconductor element 11 has a bonding surface 62A that is in contact with a second bonding portion 412. The bonding surface 62A is inclined to be away from one of the electrodes 111 as it approaches the first bonding portion 411.

As shown in FIG. 12, the second bonding portion 412 has a first portion 412A and a second portion 412B. The second portion 412B is located opposite from the first bonding portion 411 with respect to the first portion 412A. A dimension t1 of the first portion 412A in the first direction z decreases with increasing distance from the first bonding portion 411. The second portion 412B protrudes from the boundary with the first portion 412A in the first direction Z.

As shown in FIG. 12, the pillar portion 62 has a first pillar portion 621 and a second pillar portion 622. The first pillar portion 621 is in contact with the disc portion 61. The second pillar portion 622 is located opposite from the disc portion 61 with respect to the first pillar portion 621 in the first direction z. The second pillar portion 622 includes a base 622A and a protrusion 622B. As shown in FIG. 11, the base 622A is surrounded by the periphery of the first pillar portion 621 as viewed in the first direction z. The protrusion 622B protrudes toward the first bonding portion 411 from the base 622A. The protrusion 622B includes at least a portion of the bonding surface 62A. In the semiconductor device A10, the base 622A includes a portion of the bonding surface 62A.

As shown in FIGS. 2 and 6, the second wires 42 are electrically bonded to some electrodes 111 of the first semiconductor element 11 and the covered portions 311 of the first terminals 31. As a result, at least one of the first terminals 31 is electrically connected to the first semiconductor element 11. Furthermore, at least one of the second wires 42 is electrically bonded to one of the electrodes 111 and one of the covered portions 212A of the two first suspending lead portions 212 of the first die pad 21. As a result, at least one of the two first suspending lead portions 212 is electrically connected to the first semiconductor element 11. At least one of the two first suspending lead portions 212 electrically connected to the first semiconductor element 11 serves as the ground of the first semiconductor element 11. The composition of the second wires 42 includes gold. Alternatively, each of the second wires 42 may include a core material containing copper, and a covering material containing palladium (Pd) and covering the core material.

As shown in FIGS. 8 and 9, each of the second wires 42 has a third bonding portion 421 and a fourth bonding portion 422. The third bonding portion 421 is located at one end of the second wire 42. The third bonding portion 421 is electrically bonded to one of the electrodes 111 of the first semiconductor element 11. In the semiconductor device A10, the third bonding portion 421 is formed by so-called ball bonding. The fourth bonding portion 422 is located at the other end of the second wire 42. The fourth bonding portion 422 is electrically bonded to one of the covered portions 311 of the first terminals 31 and the covered portions 212A of the two first suspending lead portions 212. In the semiconductor device A10, the fourth bonding portion 422 is formed by so-called wedge bonding.

As shown in FIG. 9, a distance L1 between the first bonding portion 411 and the second bonding portion 412 of one of the first wires 41 in the first direction z is shorter than a distance L2 between the third bonding portion 421 and the fourth bonding portion 422 of one of the second wires 42 in the first direction z.

As shown in FIGS. 2 and 6, the third wires 43 are electrically connected to the second electrodes 122 of the second semiconductor element 12 and the electrodes 131 of the third semiconductor element 13. As a result, the third semiconductor element 13 is electrically connected to the second semiconductor element 12. As viewed in the first direction z, the third wires 43 extend in the second direction x. The third wires 43 are arranged in the third direction y. One of the third wires 43 extends across one of the through-holes 223 formed in the second pad portion 221 of the second die pad 22. The composition of the first wires 41 includes gold.

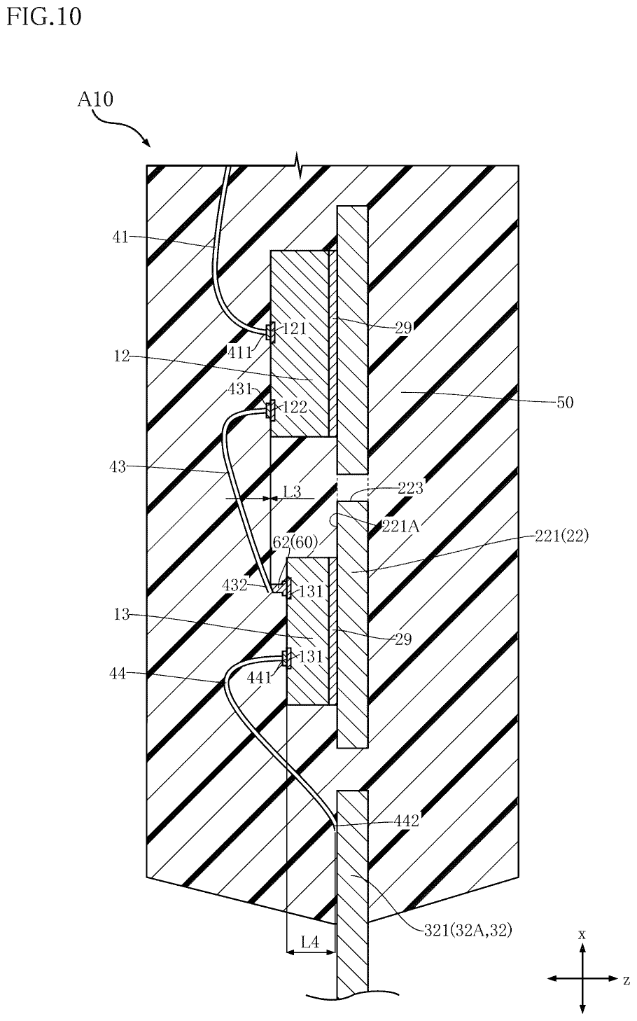

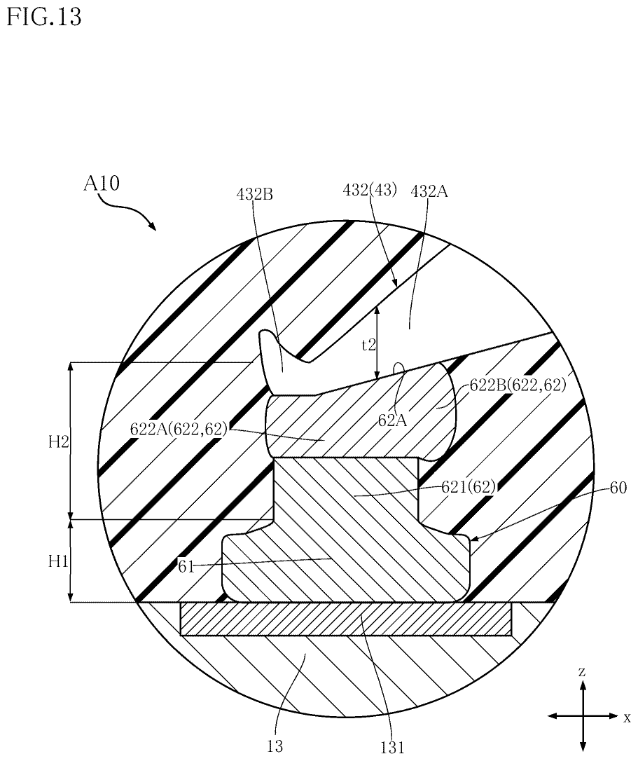

As shown in FIGS. 8 and 10, each of the third wires 43 has a fifth bonding portion 431 and a sixth bonding portion 432. The fifth bonding portion 431 is located at one end of the third wire 43. The fifth bonding portion 431 is formed by so-called ball bonding. The fifth bonding portion 431 is electrically bonded to one of the second electrodes 122 of the second semiconductor element 12. The sixth bonding portion 432 is located at the other end of the third wire 43. The sixth bonding portion 432 is formed by so-called wedge bonding. As shown in FIG. 13, the sixth bonding portion 432 is electrically bonded to the pillar portion 62 of one of the bumps 60 that are each electrically bonded to one of the electrodes 131 of the third semiconductor element 13. The dimension of the pillar portion 62 in the first direction z increases toward the fifth bonding portion 431.

As shown in FIG. 13, the pillar portion 62 of each bump 60 electrically bonded to one of the electrodes 131 of the third semiconductor element 13 has a bonding surface 62A that is in contact with a sixth bonding portion 432. The bonding surface 62A is inclined to be away from one of the electrodes 131 as it approaches the fifth bonding portion 431.

As shown in FIG. 13, the sixth bonding portion 432 has a first portion 432A and a second portion 432B. The second portion 432B is located opposite from the fifth bonding portion 431 with respect to the first portion 432A. A dimension t2 of the first portion 432A in the first direction z decreases with increasing distance from the fifth bonding portion 431. The second portion 432B protrudes from the boundary with the first portion 432A in the first direction Z.

As shown in FIGS. 2 and 6, the fourth wires 44 are electrically bonded to the electrodes 131 of the third semiconductor element 13 and the covered portions 321 of the second terminals 32. As a result, at least one of the second terminals 32 is electrically connected to the third semiconductor element 13. Furthermore, at least one of the fourth wires 44 is electrically bonded to one of the electrodes 131 and one of the covered portions 222A of the two second suspending lead portions 222 of the second die pad 22. As a result, at least one of the two second suspending lead portions 222 is electrically connected to the third semiconductor element 13. At least one of the two second suspending lead portions 222 electrically connected to the third semiconductor element 13 serves as the ground of the third semiconductor element 13. The composition of the fourth wires 44 includes gold. Alternatively, each of the fourth wires 44 may include a core material containing copper, and a covering material containing palladium and covering the core material.

As shown in FIGS. 8 and 10, each of the fourth wires 44 has a seventh bonding portion 441 and an eighth bonding portion 442. The seventh bonding portion 441 is located at one end of the fourth wire 44. The seventh bonding portion 441 is electrically bonded to one of the electrodes 131 of the third semiconductor element 13. In the semiconductor device A10, the seventh bonding portion 441 is formed by so-called ball bonding. The eighth bonding portion 442 is located at the other end of the fourth wire 44. The eighth bonding portion 442 is electrically bonded to one of the portions 321 of the second terminals 32 and the covered covered portions 222A of the two second suspending lead portions 222. In the semiconductor device A10, the eighth bonding portion 442 is formed by so-called wedge bonding.

As shown in FIG. 10, a distance L3 between the fifth bonding portion 431 and the sixth bonding portion 432 of one of the third wires 43 in the first direction z is shorter than a distance L4 between the seventh bonding portion 441 and the eighth bonding portion 442 of one of the fourth wires 44 in the first direction z.

As shown in FIG. 1, the sealing resin 50 covers the first semiconductor element 11, the second semiconductor element 12, and the third semiconductor element 13. As shown in FIG. 1, the sealing resin 50 covers a portion of each of the first die pad 21, the second die pad 22, the first terminals 31, and the second terminals 32. As shown in FIG. 6, the sealing resin 50 also covers the first wires 41, the second wires 42, the third wires 43, and the fourth wires 44. The sealing resin 50 is an insulator. The sealing resin 50 is made of a material containing epoxy resin, for example. As viewed in the first direction z, the sealing resin 50 has a rectangular shape.

As shown in FIGS. 3 to 5, the sealing resin 50 has a top surface 51, a bottom surface 52, two first side surfaces 53, and two second side surfaces 54.

As shown in FIGS. 3 to 5, the top surface 51 and the bottom surface 52 are spaced apart from each other in the first direction z. The top surface 51 and the bottom surface 52 face away from each other in the first direction z. The top surface 51 and the bottom surface 52 are substantially flat.

As shown in FIGS. 3 to 5, the two first side surfaces 53 are connected to the top surface 51 and the bottom surface 52 and spaced apart from each other in the second direction x. The exposed portions 222B of the two second suspending lead portions 222 of the second die pad 22 and the exposed portions 322 of the second terminals 32 are exposed from one of the two first side surfaces 53 that is located on a first side in the second direction x. The exposed portions 222 of the two first suspending lead portions 212 of the first die pad 21 and the exposed portions 312 of the first terminals 31 are exposed from one of the two first side surfaces 53 that is located on a second side in the second direction x.

As shown in FIGS. 3 to 5, each of the two first side surfaces 53 includes a first upper portion 531, a first lower portion 532, and a first intermediate portion 533. One end of the first upper portion 531 in the first direction z is connected to the top surface 51, and the other end of the first upper portion 531 in the first direction z is connected to the first intermediate portion 533. The first upper portion 531 is inclined to the top surface 51. One end of the first lower portion 532 in the first direction z is connected to the bottom surface 52, and the other end of the first lower portion 532 in the first direction z is connected to the first intermediate portion 533. The first lower portion 532 is inclined to the bottom surface 52. One end of the first intermediate portion 533 in the first direction z is connected to the first upper portion 531, and the other end of the first intermediate portion 533 in the first direction z is connected to the first lower portion 532. The in-plane direction of the first intermediate portion 533 is defined by the first direction z and the third direction y. As viewed in the first direction z, the first intermediate portion 533 is located outside the top surface 51 and the bottom surface 52. The exposed portions 222B of the two second suspending lead portions 222 of the second die pad 22, the exposed portions 222B of the two first suspending lead portions 212 of the first die pad 21, the exposed portions 322 of the second terminals 32, and the exposed portions 312 of the first terminals 31 are exposed from t the first intermediate portions 533 of the two first side surfaces 53.

As shown in FIGS. 3 to 5, the two second side surfaces 54 are connected to the top surface 51 and the bottom surface 52 and spaced apart from each other in the third direction y. As shown in FIG. 1, the second die pad 22, the first die pad 21, the second terminals 32, and the first terminals 31 are spaced apart from the two second side surfaces 54.

As shown in FIGS. 3 to 5, each of the two second side surfaces 54 includes a second upper portion 541, a second lower portion 542, and a second intermediate portion 543. One end of the second upper portion 541 in the first direction z is connected to the top surface 51, and the other end of the second upper portion 541 in the first direction z is connected to the second intermediate portion 543. The second upper portion 541 is inclined to the top surface 51. One end of the second lower portion 542 in the first direction z is connected to the bottom surface 52, and the other end of the second lower portion 542 in the first direction z is connected to the second intermediate portion 543. The second lower portion 542 is inclined to the bottom surface 52. One end of the second intermediate portion 543 in the first direction z is connected to the second upper portion 541, and the other end of the second intermediate portion 543 in the first direction z is connected to the second lower portion 542. The in-plane direction of the second intermediate portion 543 is defined by the first direction z and the second direction x. As viewed in the first direction z, the second intermediate portion 543 is located outside the top surface 51 and the bottom surface 52.

A motor driver circuit for an inverter is typically configured with a half-bridge circuit including a low-side (low-potential-side) switching element and a high-side (high-potential-side) switching element. The following description is provided with an assumption that these switching elements Note that the reference potential of the source are MOSFETS. of the low-side switching element and the reference potential of the gate driver for driving the low-side switching element are both ground. On the other hand, the reference potential of the source of the high-side switching element and the reference potential of the gate driver for driving the high-side switching element both correspond to a potential at an output node of the half-bridge circuit. Because the potential at the output node varies according to the drive of the high-side switching element and the low-side switching element, the reference potential of the gate driver for driving the high-side switching element varies as well. When the high-side switching element is on, the reference potential is equivalent to the voltage applied to the drain of the high-side switching element (e.g., 600 V or higher). In the semiconductor device A10, the ground of the third semiconductor element 13 and the ground of the first semiconductor element 11 are spaced apart from each other. Accordingly, in the case where the semiconductor device A10 is used as the gate driver for driving the high-side switching element, a voltage equivalent to the voltage applied to the drain of the high-side switching element is transiently applied to the ground of the first semiconductor element 11.

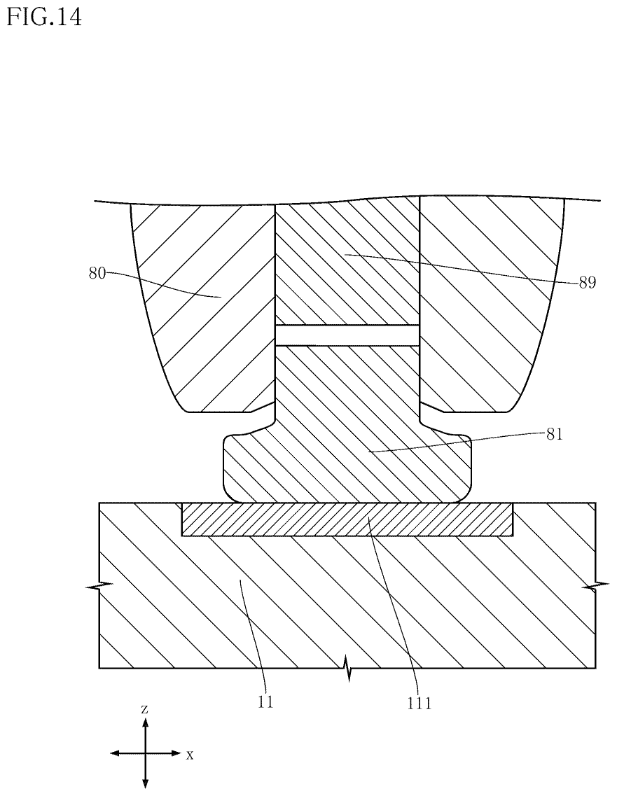

The following describes a method for forming the bumps 60 that are each electrically bonded one of the electrodes 111 of the first semiconductor element 11, with reference to FIGS. 14 to 16.

First, as shown in FIG. 14, a first bonding portion 81 is formed to be electrically bonded to one of the electrodes 111 of the first semiconductor element 11. The first bonding portion 81 is formed by ball bonding with a metal material 89 fed from a capillary 80. The metal material 89 is the same as the material used for the first wires 41. The first bonding portion 81 has a disc portion in contact with the electrode 111 and a protrusion that protrudes from the disc portion in the first direction z.

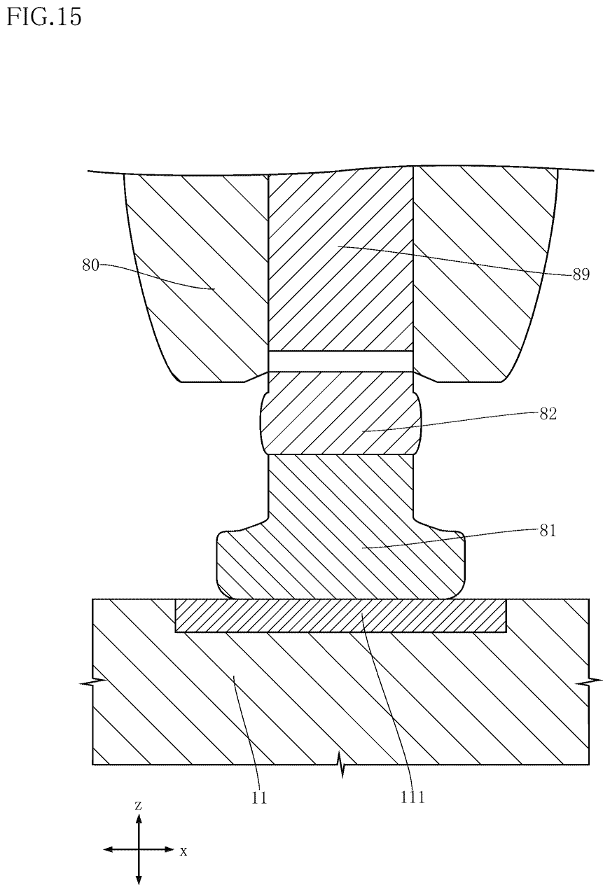

Next, as shown in FIG. 15, a second bonding portion 82 is formed to be electrically bonded to the first bonding portion 81. The second bonding portion 82 is formed by ball bonding with the metal material 89 fed from the capillary 80. The second bonding portion 82 has a disc portion in contact with the first bonding portion 81 and a protrusion that protrudes from the disc portion in the first direction z. The dimension of the disc portion in the second direction x is smaller than the dimension of the disc portion of the first bonding portion 81 in the second direction x. The dimension of the protrusion in the first direction z is smaller than the dimension of the protrusion of the first bonding portion 81 in the first direction z.

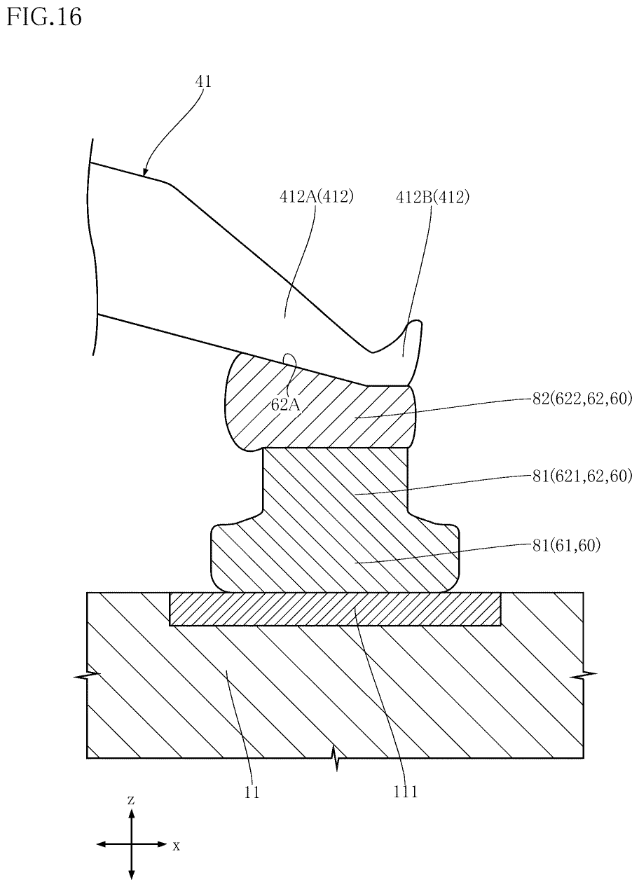

Next, as shown in FIG. 16, one of the first wires 41 is electrically bonded to the second bonding portion 82 by wedge bonding. As a result, the second bonding portion 412 of the first wire 41 is formed that is electrically bonded to the second bonding portion 82. In addition, the disc portion of the first bonding portion 81 becomes the disc portion 61 of one of the bumps 60. The protrusion of the first bonding portion 81 becomes the first pillar portion 621 of the pillar portion 62 of one of the bumps 60. Furthermore, the second bonding portion 82 becomes the second pillar portion 622 of the pillar portion 62 of one of the bumps 60. The bonding surface 62A of the pillar portion 62 is formed simultaneously with the second bonding portion 412. With the above steps, formation of the bumps 60 is completed.

Variation of the first embodiment:

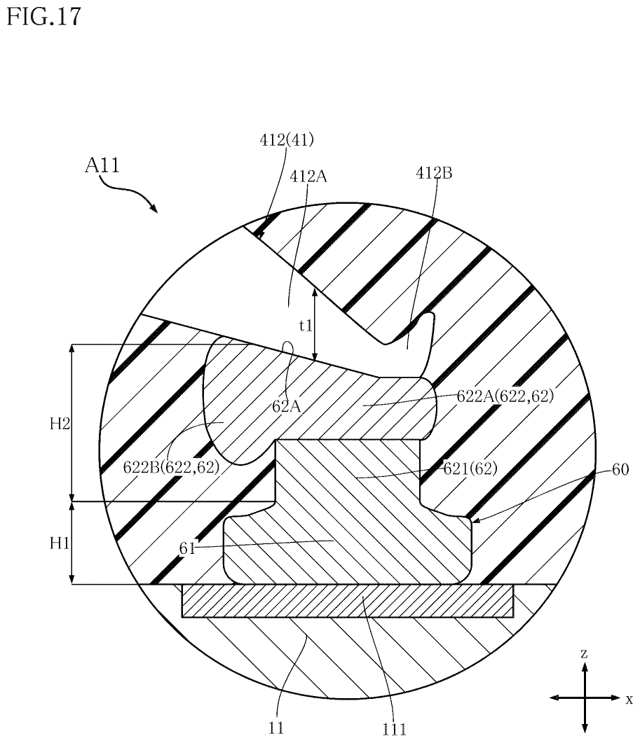

Next, a semiconductor device A11, which is a variation of the semiconductor device A10, will be described with reference to FIG. 17. Note that FIG. 17 is a cross-sectional view taken along the same (or substantially the same) plane as FIG. 12.

As shown in FIG. 17, the semiconductor device A11 is different from the semiconductor device A10 in the configuration of the bumps 60. In each of the bumps 60 that are electrically bonded to some electrodes 111 of the first semiconductor element 11, the protrusion 622B of the second pillar portion 622 of the pillar portion 62 protrudes from the disc portion 61 toward the first bonding portion 411 of one of the first wires 41.

The following describes advantages of the semiconductor device A10.

The semiconductor device A10 includes a first wire 41 having a first bonding portion 411 and a second bonding portion 412, and a bump 60 electrically bonded to an electrode 111 of a first semiconductor element 11. The bump 60 has a disc portion 61 in contact with the electrode 111 and a pillar portion 62 protruding from the disc portion 61 in the first direction z. The second bonding portion 412 is electrically bonded to the pillar portion 62. The dimension of the pillar portion 62 in the first direction z increases toward the first bonding portion 411. With this configuration, the second bonding portion 412 is arranged to be inclined with respect to a virtual surface whose normal direction is the first direction z. The position in which the second bonding portion 412 is inclined is the same as the position in which the second bonding portion 412 separates from the virtual surface as it gets closer the first bonding portion 411. This allows the entire first wire 41 to be farther away from the first semiconductor element 11. Thus, with this configuration, the semiconductor device A10 can prevent a short circuit between the semiconductor element and the wire.

The composition of the bump 60 is the same as the composition of the first wire 41. This configuration ensures excellent metal bonding between the bump 60 and the first wire 41 when the first wire 41 is electrically bonded to the bump 60.

The maximum dimension H2 of the pillar portion 62 of the bump 60 in the first direction z is at least twice the maximum dimension H1 of the disc portion 61 of the bump 60 in the first direction z. This configuration can reliably prevent the contact between the first semiconductor element 11 and the first wire 41.

The pillar portion 62 of the bump 60 has a bonding surface 62A in contact with the second bonding portion 412 of the first wire 41. The bonding surface 62A is inclined to be away from the electrode 111 of the first semiconductor element 11 as it approaches the first bonding portion 411 of the first wire 41. With this configuration, even when the second bonding portion 412 is inclined to the virtual surface whose normal direction is the first direction z, a decrease in the bonding area of the second bonding portion 412 with respect to the pillar portion 62 can be prevented.

The pillar portion 62 of the bump 60 has a first pillar portion 621 and a second pillar portion 622. The second pillar portion 622 includes a base 622A surrounded by the periphery of the first pillar portion 621 as viewed in the first direction z, and a protrusion 622B protruding toward the first bonding portion 411 of the first wire 41 from the base 622A. The protrusion 622B includes at least a portion of the bonding surface 62A. This configuration can ensure the area of the bonding surface 62A even when the dimension of the pillar portion 62 in the first direction z is increased. In addition, the entire first wire 41 can be provided further away from the first semiconductor element 11.

In the semiconductor device A11, the protrusion 622B of the second pillar portion 622 of the pillar portion 62 protrudes from the disc portion 61 of the bump 60 toward the first bonding portion 411 of the first wire 41. This configuration allows the entire first wire 41 to be provided further away from the first semiconductor element 11, and also allows the area of the bonding surface 62A to be further increased.

The semiconductor device A10 further includes a second semiconductor element 12 to which the first bonding portion 411 of the first wire 41 is electrically bonded, a first die pad 21 on which the first semiconductor element 11 is mounted, and a second die pad 22 on which the second semiconductor element 12 is mounted. The first die pad 21 and the second die pad 22 are spaced apart from each other in the second direction x. As viewed in the first direction z, the first wire 41 extends in the second direction x. With this configuration, the first wire 41 extends across the space between the first die pad 21 and a second die pad 22. In this case, when a sealing resin 50 is formed in the semiconductor device A10, the flow velocity of the melted resin material becomes relatively high between the first die pad 21 and the second die pad 22, which causes the first wire 41 to be easily bent. Thus, the semiconductor device A10 includes the bump 60 to prevent the contact between the first semiconductor element 11 and the first wire 41 even when the first wire 41 is bent.

Since the semiconductor device A10 includes the bump 60, the top of the first wire 41 (the portion of the first wire 41 farthest away from the first semiconductor element 11 in the first direction z) can be brought closer to the first semiconductor element 11. This makes it possible to reduce the height of the semiconductor device A10.

In the semiconductor device A10, a portion of each of the first die pad 21, the second die pad 22, a plurality of second terminals 32, and a plurality of first terminals 31 is exposed from one of two first side surfaces 53 of the sealing resin 50. This configuration is obtained by exposing two second suspending lead portions 222 of the second die pad 22 from the side of the sealing resin 50 located on one side in the second direction x, and exposing two first suspending lead portions 212 of the first die pad 21 from the side of the sealing resin 50 on the other side in the second direction x. In this case, the second die pad 22, the first die pad 21, the second terminals 32, and the first terminals 31 are separated from two second side surfaces 54 of the sealing resin 50. As a result, none of the second die pad 22, the first die pad 21, the second terminals 32, and the first terminals 31 is exposed from the two second side surfaces 54. This contributes to improvement of the dielectric strength of the semiconductor device A10.

In the semiconductor device A10, a plurality of through-holes 223 are formed in a second pad portion 221 of the second die pad 22 which is larger in area than a first pad portion 211 of the first die pad 21. This allows the fluidized sealing resin 50 to pass through the through-holes 223 during the manufacturing of the semiconductor device A10, thereby preventing insufficient filling of the sealing resin 50. As a result, the creation of voids in the sealing resin 50 can be effectively suppressed. This contributes to prevention of a decrease in the dielectric strength of the semiconductor device A10.

### Second Embodiment

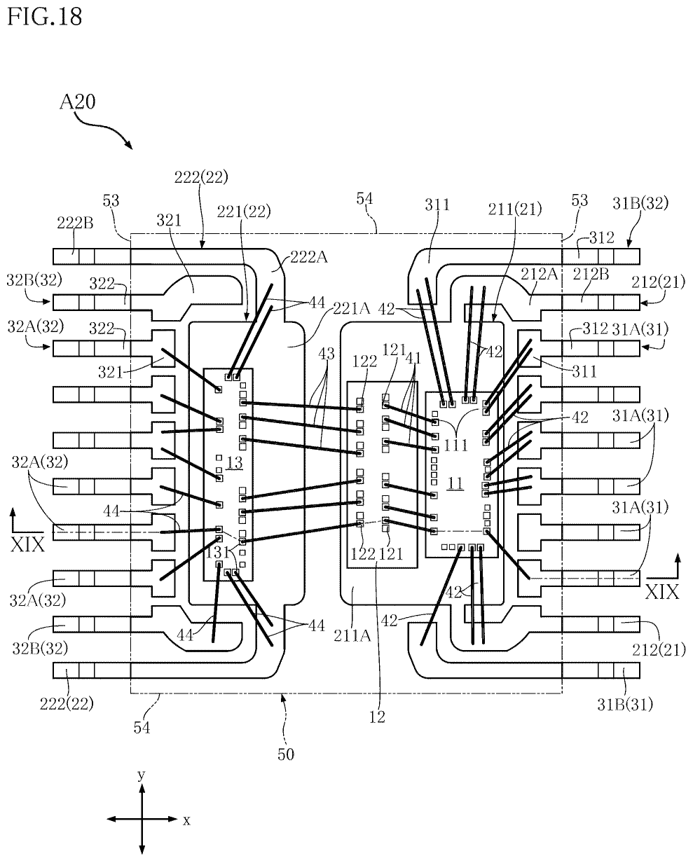

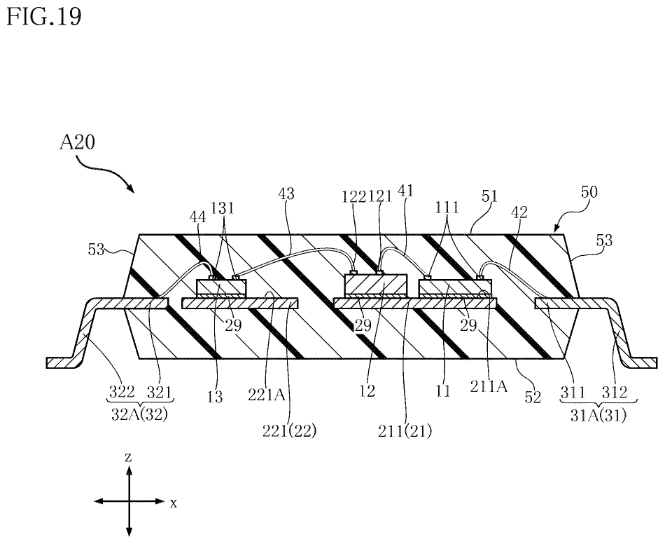

The following describes a semiconductor device A20 according to a second embodiment of the present disclosure, with reference to FIGS. 18 and 19. In these figures, elements that are the same as or similar to the elements of the semiconductor device A10 described above are provided with the same reference numerals, and descriptions thereof are omitted. In FIG. 18, the sealing resin 50 is shown by its outline only for convenience of understanding. In FIG. 18, the outline of the sealing resin 50 is indicated with an imaginary line.

The semiconductor device A20 is different from the semiconductor device A10 in the configuration of the second semiconductor element 12.

As shown in FIGS. 18 and 19, the second semiconductor element 12 is bonded to the first mounting surface 211A of the first pad portion 211 of the first die pad 21 via the bonding layer 29. Accordingly, in the semiconductor device A20, the third wires 43 extend across the space between the second pad portion 221 of the second die pad 22 and the first pad portion 211 of the first die pad 21. As such, even when the potential of the first pad portion 211 is higher than the potential of the second pad portion 221, the second semiconductor element 12 can be mounted on the first pad portion 211.

The following describes advantages of the semiconductor device A20.

The semiconductor device A20 includes a first wire 41 having a first bonding portion 411 and a second bonding portion 412, and a bump 60 electrically bonded to an electrode 111 of a first semiconductor element 11. The bump 60 has a disc portion 61 in contact with the electrode 111 and a pillar portion 62 protruding from the disc portion 61 in the first direction z. The second bonding portion 412 is electrically bonded to the pillar portion 62. The dimension of the pillar portion 62 in the first direction z increases toward the first bonding portion 411. Thus, with this configuration, the semiconductor device A20 can also prevent a short circuit between the semiconductor element and the wire. Furthermore, the semiconductor device A20 has configurations similar to the semiconductor device A10, thereby achieving the same advantages as the semiconductor device A10.

### Third Embodiment

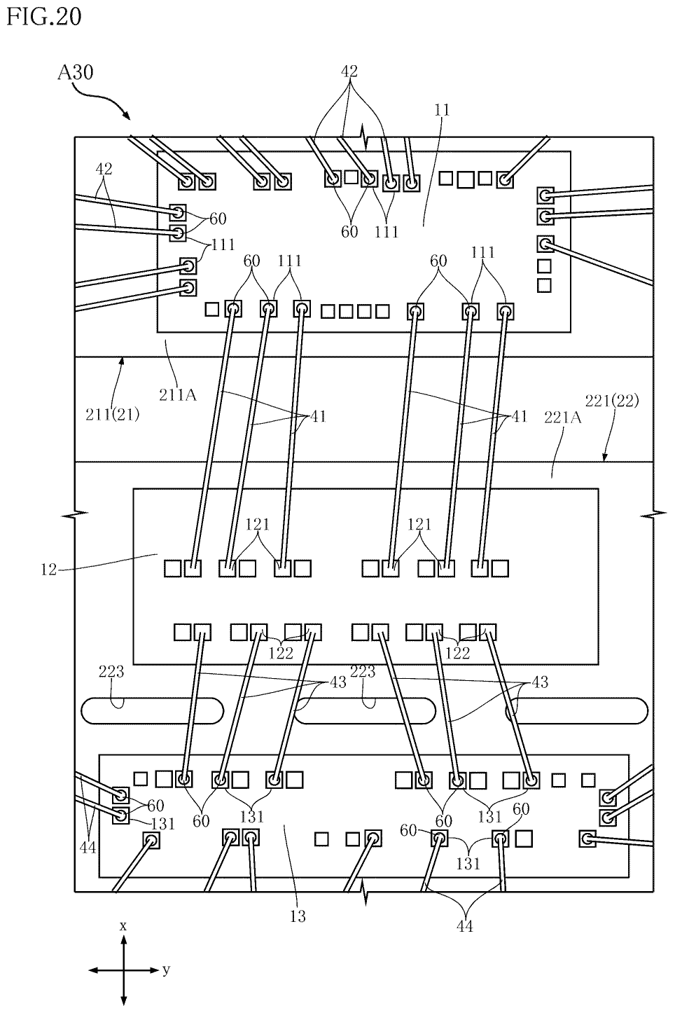

The following describes a semiconductor device A30 according to a third embodiment of the present disclosure, with reference to FIGS. 20 to 22. In these figures, elements that are the same as or similar to the elements of the semiconductor device A10 described above are provided with the same reference numerals, and descriptions thereof are omitted. FIG. 20 omits illustration of the sealing resin 50 for convenience of understanding.

The semiconductor device A30 is different from the semiconductor device A10 in the configurations of the second wires 42, the fourth wires 44, and the bumps 60.

As shown in FIG. 20, the semiconductor device A30 includes a larger number of bumps 60 that are each electrically bonded to one of the electrodes 111 of the first semiconductor element 11 than the semiconductor device A10. Furthermore, the semiconductor device A30 includes a larger number of bumps 60 that are each electrically bonded to one of the electrodes 131 of the third semiconductor element 13 than the semiconductor device A10.

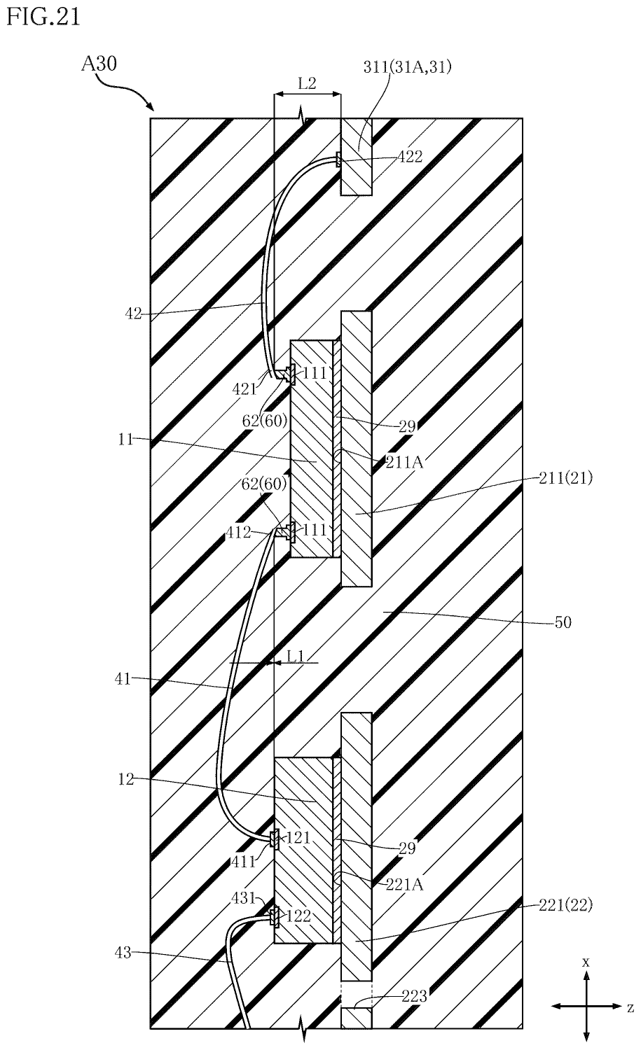

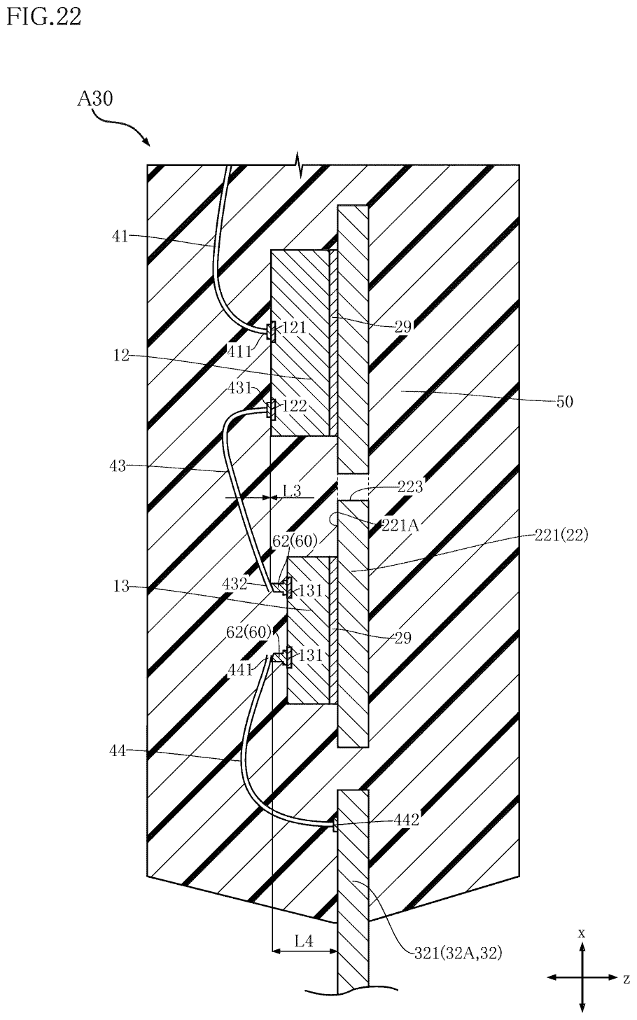

As shown in FIG. 21, the fourth bonding portion 422 of each of the second wires 42 is electrically bonded to one of the covered portions 311 of the first terminals 31 and the covered portions 212A of the two first suspending lead portions 212. In the semiconductor device A30, the fourth bonding portion 422 is formed by so-called ball bonding. The third bonding portion 421 is electrically bonded to the pillar portion 62 of one of the bumps 60 that are each electrically bonded to one of the electrodes 111 of the first semiconductor element 11. The dimension of the pillar portion 62 in the first direction z increases toward the fourth bonding portion 422. The third bonding portion 421 is formed by so-called wedge bonding.

As shown in FIG. 22, the eighth bonding portion 442 of each of the fourth wires 44 is electrically bonded to one of the covered portions 321 of the second terminals 32 and the covered portions 222A of the two second suspending lead portions 222. In the semiconductor device A30, the eighth bonding portion 442 is formed by so-called ball bonding. The seventh bonding portion 441 is electrically bonded to the pillar portion 62 of one of the bumps 60 that are each electrically bonded to one of the electrodes 131 of the third semiconductor element 13. The dimension of the pillar portion 62 in the first direction z increases toward the eighth bonding portion 442. The seventh bonding portion 441 is formed by so-called wedge bonding.

The following describes advantages of the semiconductor device A30.

The semiconductor device A30 includes a first wire 41 having a first bonding portion 411 and a second bonding portion 412, and a bump 60 electrically bonded to an electrode 111 of a first semiconductor element 11. The bump 60 has a disc portion 61 in contact with the electrode 111 and a pillar portion 62 protruding from the disc portion 61 in the first direction z. The second bonding portion 412 is electrically bonded to the pillar portion 62. The dimension of the pillar portion 62 in the first direction z increases toward the first bonding portion 411. Thus, with this configuration, the semiconductor device A30 can also prevent a short circuit between the semiconductor element and the wire. Furthermore, the semiconductor device A30 has configurations similar to the semiconductor device A10, thereby achieving the same advantages as the semiconductor device A10.

In the semiconductor device A30, a third bonding portion 421 of a second wire 42 is electrically bonded to the pillar portion 62 of a bump 60. With this configuration, the top of the second wire 42 (the portion of the second wire 42 farthest away from the first semiconductor element 11 in the first direction z) can be brought closer to the first semiconductor element 11. This makes it possible to further reduce the height of the semiconductor device A30.

The present disclosure is not limited to the above embodiments. Various design changes can be made to the specific configurations of the elements in the present disclosure.

The present disclosure includes the embodiments described in the following clauses.

### Clause 1:

A semiconductor device comprising:
a first wire including a first bonding portion located at one end and a second bonding portion located at another end;
a first semiconductor element including an electrode electrically connected to the first wire; and
a bump electrically bonded to the electrode,
wherein the bump includes a disc portion in contact with the electrode, and a pillar portion protruding from the disc portion in a first direction,
the second bonding portion is electrically bonded to the pillar portion, and
a dimension of the pillar portion in the first direction increases as approaching the first bonding portion.

### Clause 2:

The semiconductor device according to clause 1, wherein a composition of the bump is a same as a composition of the first wire.

### Clause 3:

The semiconductor device according to clause 2, wherein a maximum dimension of the pillar portion in the first direction is at least twice a maximum dimension of the disc portion in the first direction.

### Clause 4:

The semiconductor device according to any of clauses 1 to 3, wherein the pillar portion has a bonding surface in contact with the second bonding portion, and
the bonding surface is inclined to be away from the electrode as approaching the first bonding portion.

### Clause 5:

The semiconductor device according to clause 4, wherein the second bonding portion includes a first portion and a second portion located opposite from the first bonding portion with respect to the first portion,
a dimension of the first portion in the first direction decreases with increasing distance from the first bonding portion, and
the second portion protrudes from a boundary with the first portion in the first direction.

### Clause 6:

The semiconductor device according to clause 4, wherein the pillar portion includes a first pillar portion in contact with the disc portion, and a second pillar portion located opposite from the disc portion with respect to the first pillar portion in the first direction,
the second pillar portion includes a base surrounded by a periphery of the first pillar portion as viewed in the first direction, and a protrusion protruding toward the first bonding portion from the base, and
the protrusion includes at least a portion of the bonding surface.

### Clause 7:

The semiconductor device according to clause 6, wherein the base includes a portion of the bonding surface.

### Clause 8:

The semiconductor device according to clause 7, wherein the protrusion protrudes from the disc portion toward the first bonding portion.

### Clause 9:

The semiconductor device according to clause 4, further comprising a second semiconductor element electrically connected to the first semiconductor element,
wherein the first bonding portion is electrically bonded to the second semiconductor element.

### Clause 10:

The semiconductor device according to clause 9, further comprising:
a first terminal; and
a second wire including a third bonding portion electrically bonded to the first semiconductor element and a fourth bonding portion electrically bonded to the first terminal,
wherein a distance between the first bonding portion and the second bonding portion in the first direction is shorter than a distance between the third bonding portion and the fourth bonding portion in the first direction.

### Clause 11:

The semiconductor device according to clause 10, further comprising a first die pad and a second die pad that are spaced apart from each other in a second direction perpendicular to the first direction,
wherein the first semiconductor element is mounted on the first die pad,
the second semiconductor element is mounted on the second die pad, and
the first terminal is located opposite from the second die pad with respect to the first die pad in the second direction.

### Clause 12:

The semiconductor device according to clause 11, wherein as viewed in the first direction, the first wire extends in the second direction.

### Clause 13:

The semiconductor device according to clause 12, further comprising a third semiconductor element mounted on the second die pad and electrically connected to the second semiconductor element,
wherein a voltage applied to the first semiconductor element is different from a voltage applied to the third semiconductor element.

### Clause 14:

The semiconductor device according to clause 13, further comprising a second terminal electrically connected to the third semiconductor element,
wherein the second terminal is located opposite from the first die pad with respect to the second die pad in the second direction.

### Clause 15:

The semiconductor device according to clause 14, wherein the third semiconductor element is located opposite from the first semiconductor element with respect to the second semiconductor element in the second direction.

### Clause 16:

The semiconductor device according to clause 10, further comprising a sealing resin covering the first semiconductor element, the second semiconductor element, the first wire, and the second wire,
wherein the first terminal is exposed from the sealing resin.

### REFERENCE NUMERALS

A10, A20, A30: Semiconductor device
11: First semiconductor element
111: Electrode 12: Second semiconductor element
121: First electrode 122: Second electrode
13: Third semiconductor element 131: Electrode
21: First die pad 211: First pad portion
211A: First mounting surface 212: First suspending lead portion
212A: Covered portion 212B: Exposed portion
22: Second die pad 221: Second pad portion
221A: Second mounting surface
222: Second suspending lead portion
222A: Covered portion 222B: Exposed portion
223: Through-hole 29: Bonding layer
31: First terminal 31A: First inner terminal
31B: First outer terminal 311: Covered portion
312: Exposed portion 32: Second terminal
32A: Second inner terminal 32B: Second outer terminal
321: Covered portion 322: Exposed portion
41: First wire 411: First bonding portion
412: Second bonding portion 412A: First portion
412B: Second portion 42: Second wire
421: Third bonding portion 422: Fourth bonding portion
43: Third wire 431: Fifth bonding portion
432: Sixth bonding portion 432A: First portion
432B: Second portion 44: Fourth wire
441: Seventh bonding portion 442: Eighth bonding portion
50: Sealing resin 51: Top surface
52: Bottom surface 53: First side surface
531: First upper portion 532: First lower portion
54: Second side surface 533: First intermediate portion
542: Second lower portion 541: Second upper portion
543: Second intermediate portion 60: Bump
61: Disc portion 62: Pillar portion
62A: Bonding surface 621: First pillar portion
622: Second pillar portion 622A: Base
622B: Protrusion 80: Capillary
81: First bonding portion 82: Second bonding portion
89: Metal material z: First direction
x: Second direction y: Third direction

1. A semiconductor device comprising:
a first wire including a first bonding portion located at one end and a second bonding portion located at another end;
a first semiconductor element including an electrode electrically connected to the first wire; and
a bump electrically bonded to the electrode,
wherein the bump includes a disc portion in contact with the electrode, and a pillar portion protruding from the disc portion in a first direction,
the second bonding portion is electrically bonded to the pillar portion, and
a dimension of the pillar portion in the first direction increases as approaching the first bonding portion.

2. The semiconductor device according to claim 1, wherein a composition of the bump is a same as a composition of the first wire.

3. The semiconductor device according to claim 2, wherein a maximum dimension of the pillar portion in the first direction is at least twice a maximum dimension of the disc portion in the first direction.

4. The semiconductor device according to claim 1, wherein the pillar portion has a bonding surface in contact with the second bonding portion, and
the bonding surface is inclined to be away from the electrode as approaching the first bonding portion.

5. The semiconductor device according to claim 4, wherein the second bonding portion includes a first portion and a second portion located opposite from the first bonding portion with respect to the first portion,
a dimension of the first portion in the first direction decreases with increasing distance from the first bonding portion, and
the second portion protrudes from a boundary with the first portion in the first direction.

6. The semiconductor device according to claim 4, wherein the pillar portion includes a first pillar portion in contact with the disc portion, and a second pillar portion located opposite from the disc portion with respect to the first pillar portion in the first direction,
the second pillar portion includes a base surrounded by a periphery of the first pillar portion as viewed in the first direction, and a protrusion protruding toward the first bonding portion from the base, and
the protrusion includes at least a portion of the bonding surface.

7. The semiconductor device according to claim 6, wherein the base includes a portion of the bonding surface.

8. The semiconductor device according to claim 7, wherein the protrusion protrudes from the disc portion toward the first bonding portion.

9. The semiconductor device according to claim 4, further comprising a second semiconductor element electrically connected to the first semiconductor element,
wherein the first bonding portion is electrically bonded to the second semiconductor element.

10. The semiconductor device according to claim 9, further comprising:
a first terminal; and
a second wire including a third bonding portion electrically bonded to the first semiconductor element and a fourth bonding portion electrically bonded to the first terminal,
wherein a distance between the first bonding portion and the second bonding portion in the first direction is shorter than a distance between the third bonding portion and the fourth bonding portion in the first direction.

11. The semiconductor device according to claim 10, further comprising a first die pad and a second die pad that are spaced apart from each other in a second direction perpendicular to the first direction,
wherein the first semiconductor element is mounted on the first die pad,
the second semiconductor element is mounted on the second die pad, and
the first terminal is located opposite from the second die pad with respect to the first die pad in the second direction.

12. The semiconductor device according to claim 11, wherein as viewed in the first direction, the first wire extends in the second direction.

13. The semiconductor device according to claim 12, further comprising a third semiconductor element mounted on the second die pad and electrically connected to the second semiconductor element,
wherein a voltage applied to the first semiconductor element is different from a voltage applied to the third semiconductor element.

14. The semiconductor device according to claim 13, further comprising a second terminal electrically connected to the third semiconductor element,
wherein the second terminal is located opposite from the first die pad with respect to the second die pad in the second direction.

15. The semiconductor device according to claim 14, wherein the third semiconductor element is located opposite from the first semiconductor element with respect to the second semiconductor element in the second direction.

16. The semiconductor device according to claim 10, further comprising a sealing resin covering the first semiconductor element, the second semiconductor element, the first wire, and the second wire,
wherein the first terminal is exposed from the sealing resin.
